(19) United States
(12) Patent Application Publication
(10) Pub. No.: US 2007/0134929 A1
(43) Pub. Date: Jun. 14, 2007

(54) Etching method and etching apparatus

(76) Inventor: Shuji Hirao, Osaka (JP)

Correspondence Address: MCDERMOTT WILL & EMERY LLP, 600 13TH STREET, N.W., WASHINGTON, DC, 20005-3096, US

(21) Appl. No.: 11/580,945

(22) Filed: Oct. 16, 2006

(30) Foreign Application Priority Data
Dec. 14, 2005 (JP) 2005-360561

(51) Int. Cl. H01L 21/465; C23F 1/00

(52) U.S. Cl. 438/748; 438/749; 438/754; 156/345.11; 156/345.21

(57) ABSTRACT

While a semiconductor substrate having a metal film formed thereover by electrolytic plating is rotated, an etching solution for the metal film is supplied to the peripheral portion of the metal film at a first flow rate and then the etching solution is continuously supplied at a second flow rate, which is lower than the first flow rate.

### BACKGROUND OF THE INVENTION

1. Field of the Invention

The present invention relates to a method for etching part of a metal film formed over a peripheral portion of a semiconductor substrate, and an etching apparatus for removing that part of the metal film.

2. Description of the Related Art

Conventionally, aluminum (Al) has been mainly used as material of interconnects in LSIs formed on semiconductor substrates made of silicon (Si). In recent years, however, as packaging density on and speed of semiconductor integrated circuits have been increasing, copper (Cu), which has lower resistance than Al and high electromigration (EM) resistance, has been attracting attention as material of interconnects. As a method for forming a Cu film, an electrolytic plating method, which is excellent in filling in trenches and holes, is used. In an electrolytic plating method, a seed Cu film needs to be formed as a seed layer. Therefore, a seed Cu film is formed on the entire surface of a semiconductor substrate, and thereafter, a Cu film is formed by electrolytic plating.

FIG. 7 illustrates a typical electrolytic plating apparatus. FIGS. 8A and 8B are cross-sectional views illustrating a conventional method for forming a Cu film over the entire surface of a semiconductor substrate. Hereinafter, the typical method for forming a Cu film by electrolytic plating will be described with reference to these figures.

The Cu film formation by electrolytic plating is performed using the electrolytic plating apparatus shown in FIG. 7, in which in a plating bath (plating tank) 21, current is passed across a cathode electrode 19 and an anode electrode 14 with the film formation surface of a semiconductor substrate 1 immersed in a plating solution containing Cu ions. The plating solution 20 is supplied by a pump 12 from a plating solution tank 11 into the plating bath 21. The plating solution 20 is supplied into the plating bath 21 through a filter 13 then circulates back to the plating solution tank 11. A straightening vane 15 is provided between the semiconductor substrate 1 and the anode electrode 14. During the film formation, the semiconductor substrate 1 is held by a substrate holder 17, and the cathode electrode 19 is in contact with a peripheral portion of the film formation surface of the semiconductor substrate 1. The cathode electrode 19 is waterproofed by a seal 18.

As shown in FIG. 8A, to form a Cu film over the semiconductor substrate 1, a thin seed Cu film 2 is first formed by sputtering or the like on the semiconductor substrate 1 having semiconductor elements and interconnect grooves formed therein.

Next, as shown in FIG. 8B, a Cu film 3 is formed on the seed Cu film 2 by using the electrolytic plating apparatus shown in FIG. 7.

### SUMMARY OF THE INVENTION

However, when the Cu film is formed by the conventional electrolytic plating method, the following problem occurs.

FIG. 9 is a view for explaining the problem occurring when the Cu film is formed by the conventional electrolytic plating method. In the process step shown in FIG. 8B, the Cu film 3 is grown by using the electrolytic plating apparatus shown in FIG. 7 with current being applied from the cathode electrode 19 that is in contact with the peripheral portion of the semiconductor substrate 1. As a result, as shown in FIG. 9, part of the Cu film 3 deposited over the peripheral portion of the semiconductor substrate 1 located closer to the cathode electrode 19 has greater thickness than part of the Cu film 3 deposited over the inner peripheral portion of the semiconductor substrate 1. The “peripheral portion of a semiconductor substrate” used herein means an area located within about 5 mm from the edge of the semiconductor substrate.

FIG. 10 shows results of measurement, in the radius direction, of the thickness of a Cu film formed over a 300 mm diameter wafer (semiconductor substrate) by electrolytic plating. In the 300 mm diameter semiconductor substrate, a portion thereof located within 5 mm from the edge, that is, a portion thereof located more than 145 mm away from the center, is the peripheral portion of the semiconductor substrate.

As can be seen from FIG. 10, the Cu film has a substantially uniform thickness in its portion which is within 145 mm from the center of the semiconductor substrate. But the thickness of the Cu film sharply increases in the portion thereof which is located more than 145 mm away from the center, i.e., in the portion thereof located over the peripheral portion of the semiconductor substrate. This thick portion of the Cu film formed over the peripheral portion of the semiconductor substrate remains over the semiconductor substrate as a residue, even after a typical chemical mechanical polishing process is performed, and causes film peeling in subsequent process steps.

As a means for solving this problem, the Japanese Laid-Open Publication No. 2002-170802 was proposed. In the Japanese Laid-Open Publication No. 2002-170802, as shown in FIG. 11A, a nozzle 30 for supplying an etching solution is placed perpendicular to a semiconductor substrate 1. With the semiconductor substrate 1 rotated, the etching solution for dissolving Cu is supplied from the supply nozzle 30 toward the peripheral portion of the semiconductor substrate 1, whereby, as shown in FIG. 11B, part of a Cu film 3 and part of a seed Cu film 2 formed on the peripheral portion of the semiconductor substrate 1 are removed.

In this case, however, the peripheral portion of the semiconductor substrate 1 is exposed by the etching, that is, the part of the Cu film 3 formed over the peripheral portion of the semiconductor substrate 1 is removed until the semiconductor substrate 1 is exposed. This causes a problem in that a region in which an LSI is to be formed becomes small.

It is therefore an object of the present invention to make the thickness of a metal film formed over a semiconductor substrate by electrolytic plating become uniform over the entire surface of the semiconductor substrate.

A first inventive etching method includes the steps of: (a) with a semiconductor substrate rotated, supplying an etching solution at a first flow rate to part of a metal film formed over a peripheral portion of the semiconductor substrate, thereby etching the part of the metal film; and (b) after the step (a), with the semiconductor substrate rotated, supplying the etching solution at a second flow rate, which is lower than the first flow rate, to the part of the metal film formed over the peripheral portion of the semiconductor substrate, thereby etching the part of the metal film.

According to this method, the amount of etching of the part of the metal film formed over the peripheral portion of the semiconductor substrate can be adjusted by combining the steps (a) and (b), whereby it is possible to make the thickness of the metal film uniform. Films that can be etched by this method include not only copper films formed by electrolytic plating but also films of various materials formed by various methods.

A second inventive etching method includes the steps of: (a) with a semiconductor substrate rotated at a first rotation speed, supplying an etching solution to part of a metal film formed over a peripheral portion of the semiconductor substrate, thereby etching the part of the metal film; and (b) after the step (a), with the semiconductor substrate rotated at a second rotation speed which is higher than the first rotation speed, supplying the etching solution to the part of the metal film formed over the peripheral portion of the semiconductor substrate, thereby etching the part of the metal film.

In this manner, it is also possible to make the thickness of the metal film uniform by changing the rotation speed of the semiconductor substrate when etching is performed.

A third inventive etching method for etching part of a metal film formed over a peripheral portion of a semiconductor substrate by supplying an etching solution to the part of the metal film from a nozzle with the semiconductor substrate rotated includes the steps of: (a) supplying the etching solution with the nozzle inclined at a first angle with respect to a center of the semiconductor substrate, thereby performing etching; and (b) after the step (a), supplying the etching solution with the nozzle inclined at a second angle, which is different form the first angle, with respect to the center of the semiconductor substrate, thereby performing etching.

A fourth inventive etching method for etching part of a metal film formed over a peripheral portion of a semiconductor substrate by supplying an etching solution to the part of the metal film from first and second nozzles with the semiconductor substrate rotated includes the steps of: (a) supplying the etching solution from the first nozzle inclined at a first angle with respect to a center of the semiconductor substrate and from the second nozzle inclined at a second angle, which is different from the first angle, with respect to the center of the semiconductor substrate, thereby performing etching; and (b) after the step (a), supplying the etching solution from the second nozzle, thereby performing etching.

A first inventive etching apparatus includes: a substrate holder for holding a semiconductor substrate; a nozzle for supplying an etching solution onto the semiconductor substrate; a nozzle rotator for rotating the nozzle; and a nozzle holder for holding the nozzle rotator.

Then, the direction in which the etching solution is supplied to the film can be changed by rotating the nozzle, whereby it is possible to etch just the intended portion in the desired amount. Therefore, when this etching apparatus is used, the film thickness can be easily made uniform.

A second inventive etching apparatus includes: a substrate holder for holding a semiconductor substrate; a first nozzle for supplying an etching solution onto the semiconductor substrate at a first angle with respect to a center of the semiconductor substrate; a first nozzle holder for holding the first nozzle; a second nozzle for supplying the etching solution onto the semiconductor substrate at a second angle, which is different from the first angle, with respect to the center of the semiconductor substrate; and a second nozzle holder for holding the second nozzle.

Then, the etching can be performed by combining the first and second nozzles in an appropriate manner, which enables the amount of etching to be adjusted more effectively.

### BRIEF DESCRIPTION OF THE DRAWINGS

FIGS. 1A to 1D are cross-sectional views illustrating an etching method according to a first embodiment of the present invention.

FIG. 2 shows profiles of the thickness of a Cu film formed over a semiconductor substrate by electrolytic plating.

FIG. 3 shows the amount of etching of a Cu film achieved when the flow rate of an etching solution was changed.

FIG. 4 shows the amount of etching of a Cu film achieved when the flow rate of an etching solution was changed, and the amount of etching of the Cu film achieved when the etching solution was supplied at two different flow rates, and the thickness of the Cu film after this etching.

FIGS. 5A to 5D illustrate an etching apparatus according to a second embodiment of the present invention.

FIGS. 6A and 6B illustrate an etching apparatus according to a modified example of the second embodiment.

FIG. 7 is a view for explaining a typical electrolytic plating method.

FIGS. 8A and 8B are cross-sectional views illustrating a conventional method for forming a metal film over a semiconductor substrate.

FIG. 9 is a view for explaining a problem occurring when a Cu film is formed by a conventional electrolytic plating method.

FIG. 10 shows the thickness of a Cu film formed by electrolytic plating.

FIGS. 11A and 11B are views for explaining a problem occurring when a Cu film is formed by a conventional electrolytic plating method.

### DETAILED DESCRIPTION OF THE INVENTION

### First Embodiment

Hereinafter, a method for etching part of a metal film formed over a peripheral portion of a semiconductor substrate, and an etching apparatus for removing that part of the metal film according to a first embodiment of the present invention will be described.

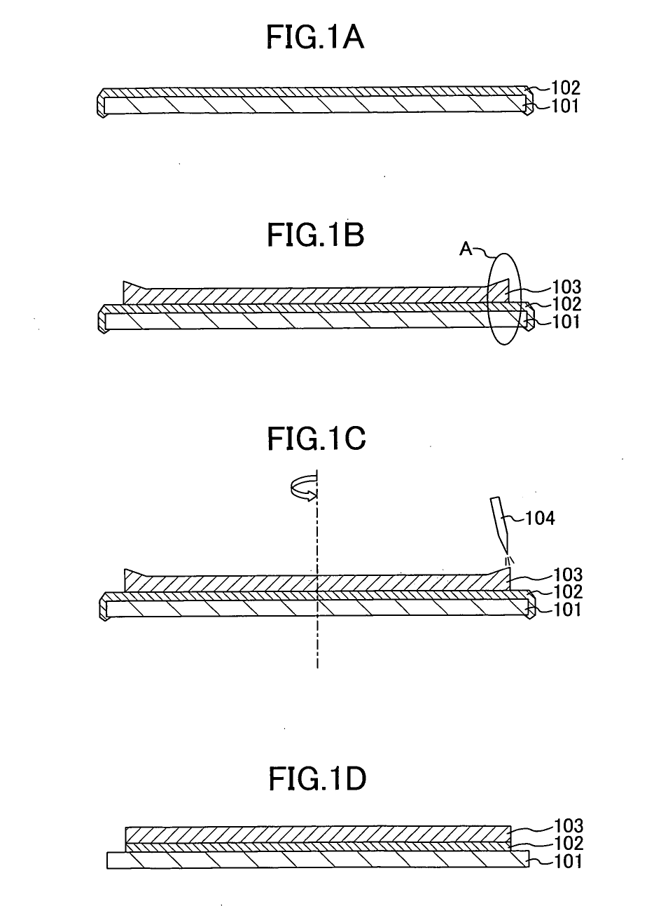

FIGS. 1A to 1D are cross-sectional views illustrating a method for etching part of a metal film formed over a peripheral portion of a semiconductor substrate according to the first embodiment of the present invention.

First, as shown in FIG. 1A, a seed Cu film 102 having a thickness of about 30 nm is formed on a semiconductor substrate 101 by a sputtering process. In this process, the seed Cu film 102 is formed on the side faces of the semiconductor substrate 101 as well.

Next, as shown in FIG. 1B, a Cu film 103 is deposited on the seed Cu film 102 to a thickness of about 600 nm by electrolytic plating. At this time, the Cu film 103 has a larger thickness in a peripheral portion A than in the other portion. This is because current from a cathode electrode is supplied to the peripheral portion of the semiconductor substrate 101, and it is difficult to prevent that part of the Cu film formed in the peripheral portion A from having the large thickness.

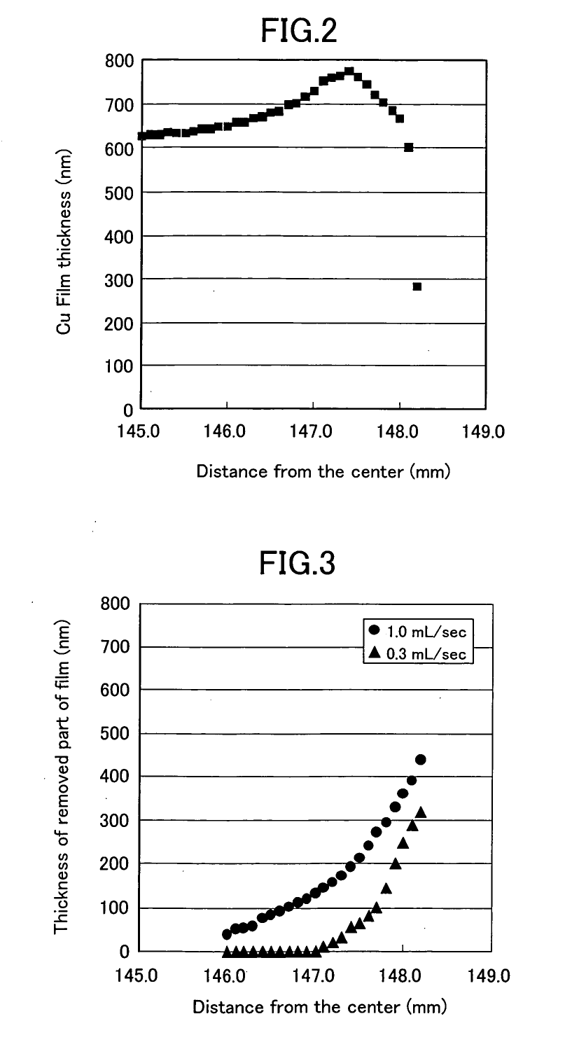

FIG. 2 shows profiles of the thickness of the Cu film formed over the semiconductor substrate by the electrolytic plating. FIG. 2 shows in enlarged dimension only the peripheral portion of the semiconductor substrate. As shown in FIG. 2, the part of the Cu film formed over the inner peripheral portion of the semiconductor substrate 101 has a thickness of 600 nm, while the part of the Cu film 103 formed over the peripheral portion of the semiconductor substrate 101 has a thickness exceeding 750 nm.

Subsequently, as shown in FIG. 1C, while the semiconductor substrate 101 is rotated, a nozzle of a diameter of about 1 mm for supplying an etching solution for the Cu films is placed close to the part of the Cu film 103 formed over the peripheral portion of the semiconductor substrate 101 and the Cu films are etched.

In this process, the etching solution is first supplied at a first flow rate to the part of the Cu film 103 formed over the peripheral portion of the semiconductor substrate 101, and thereafter, the etching solution is supplied at a second flow rate which is lower than the first flow rate. For example, the first flow rate is 1.0 mL/sec and the second flow rate is 0.3 mL/sec, the etching solution is supplied at the first flow rate for three seconds and supplied at the second flow rate for five seconds, and the semiconductor substrate 101 is rotated at a rotation speed of 300 rpm. As the etching solution, a mixed solution of sulfuric acid and hydrogen peroxide solution, for example is used. The nozzle for supplying the etching solution is directed slightly outwardly of the semiconductor substrate 101. In this process step, when the thickness of part of the Cu film 103 is greater than a predetermined thickness and the superfluous thickness is compared to the predetermined thickness, that part of the Cu film 103 corresponding to the superfluous thickness is etched away. In the fabrication method of this embodiment, the predetermined thickness of the Cu film 103 is 600 nm, and the part of the Cu film 103 whose thickness exceeds 5% of the predetermined thickness (i.e., the part of the Cu film 103 whose thickness exceeds 630 nm) substantially corresponds to the part of the Cu film 103 formed over the peripheral portion of the semiconductor substrate 101.

In this manner, the etching solution is supplied at the two different flow rates, whereby it is possible to adjust the amount of etching of the part of the Cu film 103 formed over the peripheral portion of the semiconductor substrate 101. Ths enables the Cu film 103 to have a uniform thickness over the entire surface of the semiconductor substrate 101, as shown in FIG. 1D.

Next, it will be described why the above-described method enables the Cu film 103 formed over the semiconductor substrate 101 to have a uniform thickness.

FIG. 3 shows the amount of etching of the Cu film 103 achieved when the flow rate of the etching solution was changed. FIG. 3 indicates results (solid circles in the figure) obtained in a case where the etching solution was supplied at a flow rate of 1.0 mL/sec for five seconds and results (solid triangles in the figure) obtained in a case where the etching solution was supplied at a flow rate of 0.3 mL/sec for five seconds. In both cases, the etching solution was supplied with the position of the nozzle fixed, and the semiconductor substrate 101 was rotated at a rotation speed of 300 rpm.

As can be seen from FIG. 3, the etching profiles were changed by changing the flow rate of the etching solution. To be specific, when the etching solution was supplied at the higher flow rate, part of the Cu film 103 located close to the center of the semiconductor substrate 101, that is, part of the Cu film 103 formed over the inner peripheral portion of the semiconductor substrate 101, was also etched. This is because when the etching solution is supplied to the semiconductor substrate at the higher flow rate, the etching solution is more likely to spread. At this time, since the semiconductor substrate 101 is rotated, the etching solution supplied onto the Cu film 103 does not uniformly spread to the center of the semiconductor substrate, but spreads in accordance with the rotation speed (or the centrifugal force). Therefore, it is possible to make the thickness of the Cu film 103 uniform by utilizing the difference in the profiles of the amount of etching of the Cu film 103 occurring due to the difference in the flow rate of the etching solution.

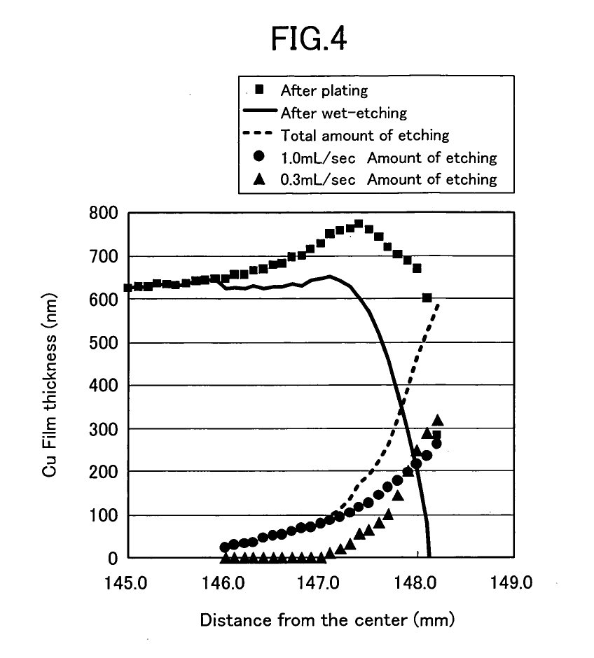

FIG. 4 shows the amount of etching of the Cu film 103 achieved when the flow rate of the etching solution was changed, and the amount of etching of the Cu film 103 achieved when the etching solution was supplied at two different flow rates, and the thickness of the Cu film after this etching. Specifically, FIG. 4 shows the amount of etching (indicated by solid circles in the figure) in a case where the etching solution was supplied at a flow rate of 1.0 mL/sec for three seconds with the nozzle position fixed; the amount of etching (indicated by solid triangles in the figure) in a case where the etching solution was supplied at a flow rate of 0.3 mL/sec for five seconds with the nozzle position fixed; and the total amount of etching (indicated by a dotted line) in a case where etching was performed at a flow rate of 1.0 mL/sec and then at a flow rate of 0.3 mL/sec, and the thickness (indicated by a solid line) of the Cu film after this etching. The semiconductor substrate 101 had a diameter of 300 mm. In this case, as described above, the peripheral portion of the semiconductor substrate 101 means the portion of the semiconductor substrate 101 located within 5 mm from the edge of the semiconductor substrate 101, i.e., the portion of the semiconductor substrate 101 located more than 145 mm away from the center of the semiconductor substrate 101.

As shown in FIG. 4, it is possible to adjust the amount of etching of the part of the Cu film 103 formed over the peripheral portion of the semiconductor substrate 101 by supplying the etching solution to the Cu film at the different flow rates. This allows the part of the Cu film 103 formed over the peripheral portion of the semiconductor substrate 101 to have a thickness that is close to the thickness of the part of the Cu film 103 formed over the inner peripheral portion of the semiconductor substrate 101, whereby the thickness of the Cu film 103 becomes uniform. In the example shown in FIG. 4, part of the Cu film 103 formed over part of the peripheral portion of the semiconductor substrate 101 that is located 145 mm to 147 mm away from the center of the semiconductor substrate 101 has a thickness close to the thickness of the part of the Cu film 103 formed over the inner peripheral portion of the semiconductor substrate 101. Therefore, the thickness of the Cu film 103 becomes uniform in its portion located within 147 mm from the center, such that it is possible to increase the area (the chip area) in which semiconductor elements are to be fabricated, as compared with the conventional case. Furthermore, the amount of etching can be adjusted so that no etching residue is left. This also prevents the Cu film from peeling off from the peripheral portion. By the etching described above, the part of the Cu film 103 formed over the portion of the semiconductor substrate 101 located within about 2 mm from the edge of the semiconductor substrate 101 is almost completely removed. In this manner, the removal of the edge of the Cu film 103 also prevents the Cu film 103 from peeling off from the peripheral portion of the semiconductor substrate 101.

If the edge of the Cu film 103 is removed at the low flow rate first, the upper surface of the etched part of the Cu film becomes steep. In that case, even if the flow rate of the etching solution is increased later, the etching solution does not effectively spread toward the center of the semiconductor substrate. Therefore, in the etching method of this embodiment, it is preferable that the flow rate of the etching solution be increased in the first-stage etching and then decreased in the second-stage etching.

In the method of this embodiment, the nozzle for supplying the etching solution is directed slightly outwardly of the semiconductor substrate, but the nozzle may be directed perpendicular to the semiconductor substrate or directed to the center of the semiconductor substrate.

Also, in the etching method of this embodiment, an etching apparatus which includes a fixed nozzle may be used, or an etching apparatus according to the present invention that will be described later may be used.

Furthermore, in the etching method of this embodiment, the exemplary case, in which the Cu film formed by electrolytic plating is planarized, is described. Nevertheless, metal films other than the Cu film formed by electrolytic plating may also be planarized in the same manner. In those cases, however, appropriate etching solutions that can etch those metal films need to be used.

Moreover, in the etching method of this embodiment, the exemplary case, in which the 300 mm diameter wafer is used as the semiconductor substrate, is described. Nevertheless, a wafer having a different diameter may also be used as the semiconductor substrate. In that case, by performing the above-described two-stage etching, it is also possible to adjust the amount of etching of part of a Cu film formed over the peripheral portion of the semiconductor substrate 101 located within 5 mm from the edge of the semiconductor substrate 101.

—First Modified Example of the Etching Method of the First Embodiment of the Present Invention—

In the etching process shown in FIG. 1C, instead of changing the flow rate of the etching solution that is supplied to the Cu film 103, the rotation speed of the semiconductor substrate 101 may be changed so that the semiconductor substrate 101 is rotated at two or more different speeds. In that case, the part of the Cu film 103 formed over the peripheral portion of the semiconductor substrate 101 should be etched with the semiconductor substrate 101 rotated at a low rotation speed first, and then the part of the Cu film 103 formed over the peripheral portion of the semiconductor substrate 101 should be etched with the semiconductor substrate 101 rotated at a high rotation speed. More specifically, in the case of a 300 mm diameter wafer, for example, the Cu film 103 is first etched for three seconds with the semiconductor substrate 101 rotated at a rotation speed lower than 300 rpm, and then the rotation speed of the semiconductor substrate 101 is increased to 300 rpm or higher, and the Cu film 103 is etched for five seconds at this increased rotation speed.

When the substrate rotation speed is low, the etching solution spreads to a large extent toward the center of the semiconductor substrate, and when the substrate rotation speed is high, the etching solution spreads to a small extent due to the centrifugal force. Therefore, by combining etching processes performed at the different substrate rotation speeds, the amount of etching of the part of the Cu film 103 formed over the peripheral portion of the semiconductor substrate 101 can be adjusted in the same manner as in the case where the flow rate of the etching solution is changed. As a result, the entire upper surface of the Cu film 103 is planarized and hence the thickness of the Cu film 103 becomes uniform. In etching the Cu film 103, it is preferable that the etching be performed at a low substrate rotation speed first and thereafter at a high substrate rotation speed.

In the etching process, if the substrate rotation speed and the flow rate of the etching solution are both changed, it is possible to adjust the amount of etching in a wider range.

—Second Modified Example of the Etching Method of the First Embodiment of the Present Invention—

In the etching process shown in FIG. 1C, instead of changing the flow rate of the etching solution that is supplied to the Cu film 103 and the rotation speed of the semiconductor substrate 101, the angle at which the etching solution is supplied may be changed so that the etching solution is supplied at two or more different angles. More specifically, first, the Cu film 103 is etched for three seconds with the head of the nozzle directed toward the center of the semiconductor substrate 101, and then the Cu film 103 is etched for five seconds with the head of the nozzle directed outwardly of the semiconductor substrate 101. This method also enables the Cu film 103 to have a uniform thickness. In this method, the nozzle is preferably directed more outwardly of the semiconductor substrate 101 in the second-stage etching than in the first-stage etching.

### Second Embodiment

Hereinafter, a method for etching a metal film formed over a semiconductor substrate according to a second embodiment of the present invention will be described.

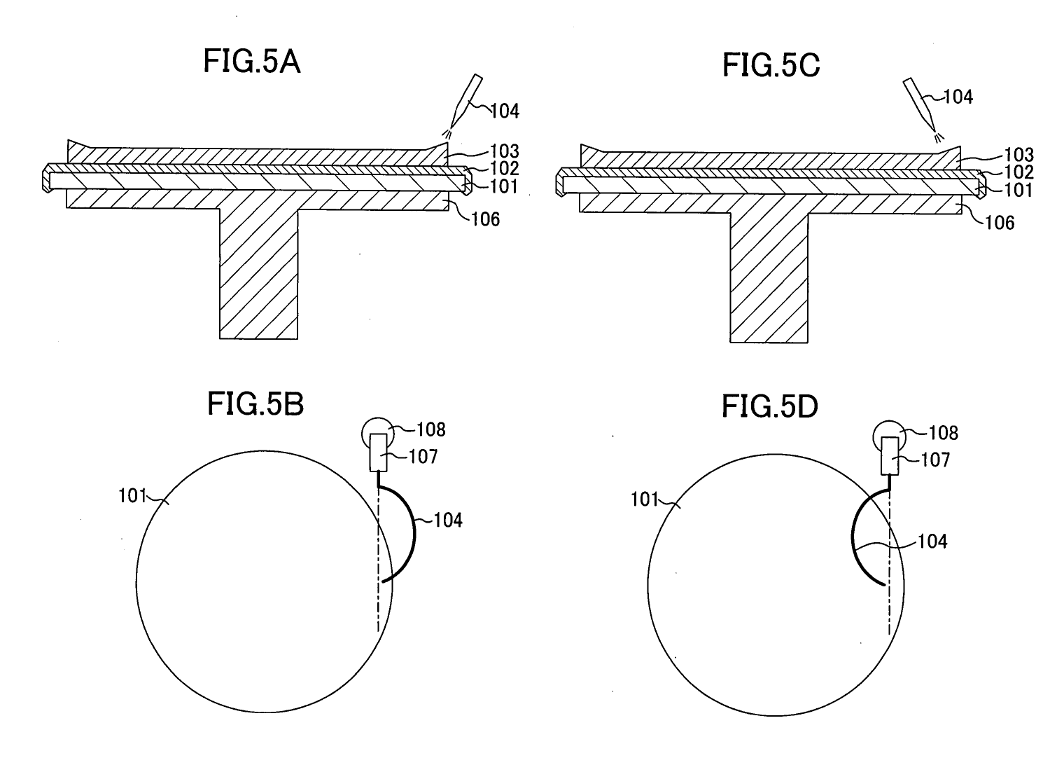

FIGS. 5A to 5D illustrate an apparatus for etching a metal film formed over a semiconductor substrate according to the second embodiment of the present invention. FIGS. 5A and 5B are a cross-sectional view and a plan view, respectively, of the etching apparatus in which a nozzle is directed inwardly during etching process. FIGS. 5C and 5D are a cross-sectional view and a plan view, respectively, of the etching apparatus in which the nozzle is directed outwardly during etching process.

As shown in FIGS. 5A to 5D, the etching apparatus of this embodiment holds a semiconductor substrate 101 and includes a rotatable substrate holder 106, a nozzle 104 for supplying an etching solution, a nozzle rotator 107 for rotating the nozzle 104 to thereby change the angle at which the etching solution is supplied, and a nozzle holder 108 for holding the nozzle rotator 107. The nozzle rotator 107 is designed so as to rotate on the nozzle holder 108. The internal diameter of the nozzle 104 is about 1 mm, for example. The substrate holder 106 rotates on the line that goes through the center of the semiconductor substrate 101 and is perpendicular to the principal surface of the semiconductor substrate.

When the etching apparatus of this method is used, the angle at which the etching solution is supplied can be changed, and therefore a Cu film 103 can be etched in the following manner.

First, as shown in FIGS. 5A and 5B, the semiconductor substrate 101 with the Cu film 103 formed thereover is placed on the substrate holder 106. And with the head of the nozzle 104 directed toward the center of the semiconductor substrate 101 (wafer), an etching solution is supplied for three seconds onto the Cu film 103 formed over the semiconductor substrate 101. At this time, the substrate rotation speed is lower than 300 rpm and the flow rate of the etching solution is 0.5 mL/sec, for example. As the etching solution, a mixed solution of sulfuric acid and hydrogen peroxide solution, for example, is used.

Next, as shown in FIGS. 5C and 5D, with the head of the nozzle 104 directed outwardly of the semiconductor substrate 101, the etching solution is supplied for five seconds. At this time, the substrate rotation speed is 300 rpm or higher, and the flow rate of the etching solution is 1.0 mL/sec, for example. By this process, exposed part of the seed Cu film 102 as well as part of the Cu film 103 formed over the peripheral portion of the semiconductor substrate 101 are removed.

As described above, in the case where the etching apparatus of this embodiment is used, the etching can be controlled not only by the flow rate of the etching solution, but also by the substrate rotation speed and the etching solution supply angle, whereby the amount of etching of the part of the Cu film 103 formed over the peripheral portion of the semiconductor substrate 101 can be controlled in a wider range.

—First Modified Example of the Etching Method of the Second Embodiment of the Present Invention—

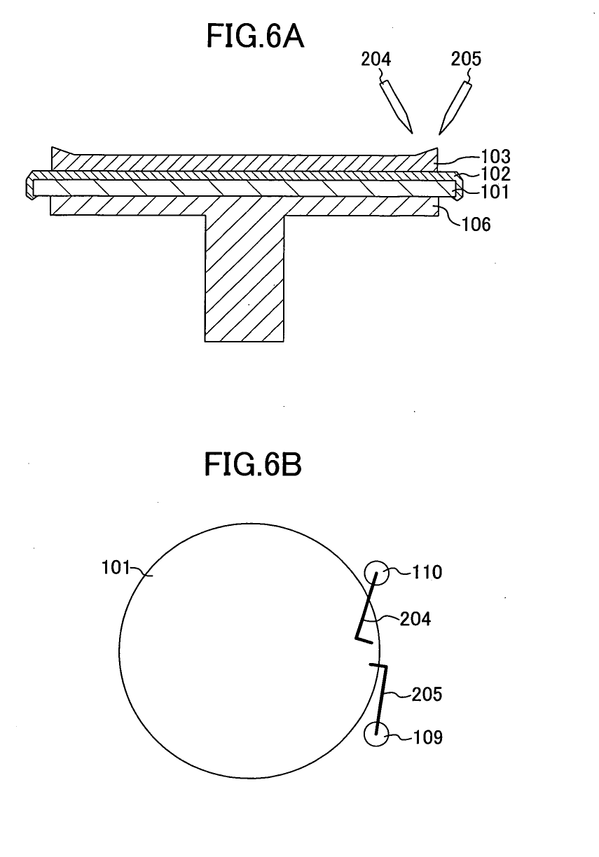

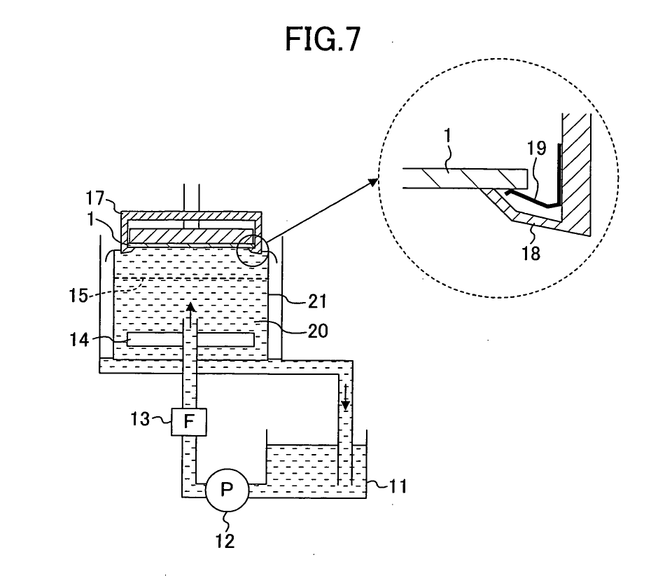

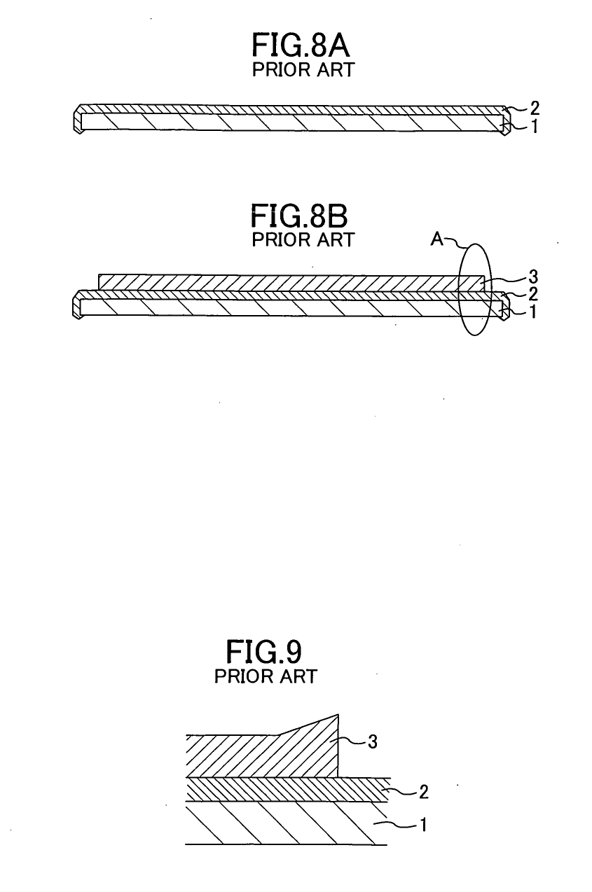

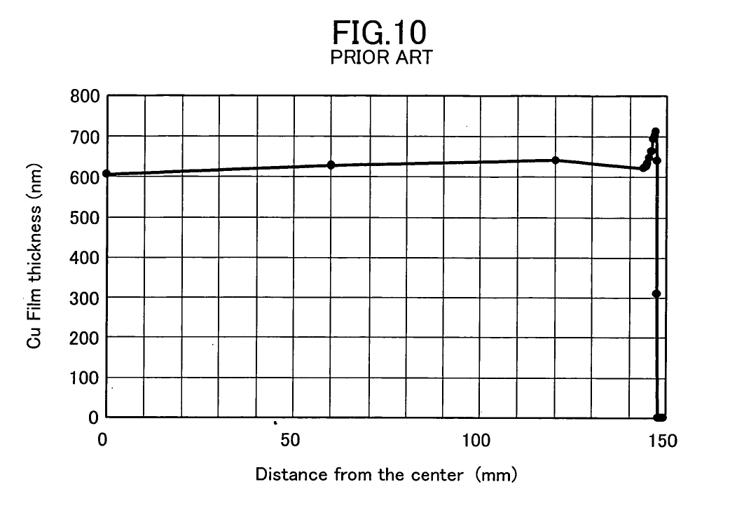

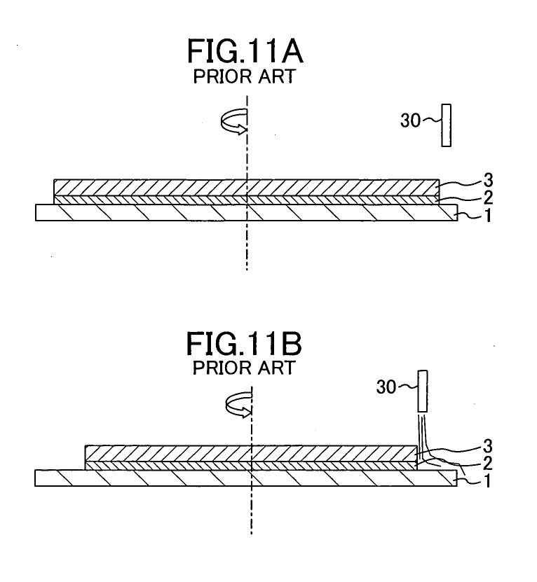

FIGS. 6A and 6B illustrate an apparatus for etching a metal film formed over a semiconductor substrate according to a modified example of the second embodiment of the present invention. As shown in FIGS. 6A and 6B, the etching apparatus according to this modified example includes a substrate holder 106 having a rotating mechanism, first and second nozzles 204 and 205 for supplying an etching solution, a first nozzle holder 110 for holding the first nozzle 204, and a second nozzle holder 109 for holding the second nozzle 205. The heads of the first and second nozzles 204 and 205 are directed at different angles with respect to the center of the semiconductor substrate 101. In the example shown in FIG. 6, the head of the first nozzle 204 is directed outwardly of the semiconductor substrate 101, while the head of the second nozzle 205 is directed toward the center of the semiconductor substrate 101.

When the above-described etching method of this embodiment is carried out by the etching apparatus of this modified example, an etching solution is first supplied from the second nozzle 205 to the part of the Cu film 103 formed over the peripheral portion of the semiconductor substrate 101, and then the etching solution is supplied from the first nozzle 204. In the etching apparatus of this modified example, it is not necessary to rotate the nozzles, which enables the angles at which the etching solution is supplied to be switched quickly.

Moreover, when the etching apparatus of this modified example is used, it is also possible to supply the etching solution simultaneously from the first and second nozzles 204 and 205 to the Cu film 103 and, thereafter, to stop the supply of the etching solution from the second nozzle 205 first. In that case, the Cu film 103 also has a uniform thickness.

As described above, the etching apparatuses and the etching methods according to the present invention are effective in making the thickness of a metal film, such as a Cu film, formed by electrolytic plating become uniform, and are thus applicable to fabrication of semiconductor devices including Cu interconnects, for example.

What is claimed is:

1. An etching method, comprising:
an etching step (a) of etching part of a metal film formed over a peripheral portion of a semiconductor substrate; and
an etching step (b) of further etching, after the step (a), the part of the metal film formed over the peripheral portion of the semiconductor substrate under a condition different from that in the step (a).

2. The method of claim 1,
wherein in the step (a), an etching solution is supplied at a first flow rate to the part of the metal film formed over the peripheral portion of the semiconductor substrate with the semiconductor substrate rotated, thereby etching the part of the metal film, and
in the step (b), the etching solution is supplied at a second flow rate, which is lower than the first flow rate, to the part of the metal film formed over the peripheral portion of the semiconductor substrate with the semiconductor substrate rotated, thereby etching the part of the metal film.

3. The method of claim 1,
wherein in the step (a), an etching solution is supplied to the part of the metal film formed over the peripheral portion of the semiconductor substrate with the semiconductor substrate rotated at a first rotation speed, thereby etching the part of the metal film; and
in the step (b), the etching solution is supplied to the part of the metal film formed over the peripheral portion of the semiconductor substrate with the semiconductor substrate rotated at a second rotation speed which is higher than the first rotation speed, thereby etching the part of the metal film.

4. The method of claim 1,
wherein in the step (a), etching is performed by supplying an etching solution from a nozzle inclined at a first angle with respect to the center of the semiconductor substrate with the semiconductor substrate rotated, and
in the step (b), etching is performed by supplying the etching solution from the nozzle inclined at a second angle, which is different from the first angle, with respect to the center of the semiconductor substrate.

5. The method of claim 1,
wherein in the step (a), etching is performed by supplying an etching solution from a first nozzle inclined at a first angle with respect to the center of the semiconductor substrate and from a second nozzle inclined at a second angle, which is different from the first angle, with respect to the center of the semiconductor substrate, and
in the step (b), etching is performed by supplying the etching solution from the second nozzle.

6. The method of claim 1,
wherein the metal film is a copper film formed by electrolytic plating.

7. An etching apparatus, comprising:
a substrate holder for holding a semiconductor substrate;
a nozzle for supplying an etching solution onto the semiconductor substrate;
a nozzle rotator for rotating the nozzle; and
a nozzle holder for holding the nozzle rotator.

8. An etching apparatus, comprising:
a substrate holder for holding a semiconductor substrate;
a first nozzle for supplying an etching solution onto the semiconductor substrate at a first angle with respect to a center of the semiconductor substrate;
a first nozzle holder for holding the first nozzle;
a second nozzle for supplying the etching solution onto the semiconductor substrate at a second angle, which is different from the first angle, with respect to the center of the semiconductor substrate; and
a second nozzle holder for holding the second nozzle.
